(19) United States
(12) Patent Application Publication
(10) Pub. No.: US 2025/0218866 A1
(43) Pub. Date: Jul. 3, 2025

(54) METHODS OF FORMING INTERCONNECT STRUCTURES INCLUDING LOW DIELECTRIC CONSTANT LAYERS AND ASSOCIATED SEMICONDUCTOR PROCESSING SYSTEMS AND STRUCTURES

(71) Applicant: ASM IP Holding B.V., Almere (NL)

(72) Inventor: Ivo Johannes Raaijmakers, Amersfoort (NL)

(21) Appl. No.: 18/990,574

(22) Filed: Dec. 20, 2024

Related U.S. Application Data
(60) Provisional application No. 63/615,615, filed on Dec. 28, 2023.

(51) Int. Cl. H01L 21/768; H01L 21/67

(52) U.S. Cl. CPC H01L 21/76831; H01L 21/67207; H01L 21/76837

(57) ABSTRACT

Methods for forming an interconnect structure and semiconductor processing system for forming the interconnect structure are disclosed. The methods disclosed include forming conductive elements in a conductive layer and forming a passivation layer over the conductive elements. The methods disclosed also include removing the passivation layer prior to forming a low dielectric constant layer in the trenches to prevent process induced damage in the low dielectric constant layer. The semiconductor processing systems disclosed include first, second, and third reaction chamber as well a transfer module for forming an interconnect structure.

### CROSS-REFERENCE TO RELATED APPLICATION(S)

This application claims the benefit of U.S. Provisional Application 63/615,615 filed on Dec. 28, 2023, the entire contents of which are incorporated herein by reference.

### FIELD

The present disclosure relates generally to the field of semiconductor processing methods, and associated structures and semiconductor processing systems, and to the field of device and integrated circuit manufacture. More particularly the present disclosure generally relates to methods of forming interconnect structures including low dielectric constant layers suitable for use in the manufacture of electronic devices as well semiconductor processing systems for forming interconnect structures and associated structures including interconnect structures.

### BACKGROUND

During the manufacture of devices, such as semiconductor devices, it is often desirable to deposit a low dielectric constant (low-k) material layer, e.g., to fill features (e.g., trenches or gaps) on the surface of a substrate. By way of example, a low-k material can be used as an intermetal dielectric layer, as a gap-fill in back-end-of-line processes, as insulating layers, or for other applications.

Low dielectric constant layers can be susceptible to process induced damage during device fabrication processing, such as, for example, during the fabrication of interconnect structures. The process induced damage to the low dielectric constant layer in the interconnect structure can result in an undesired shift in the dielectric constant of the material.

There is thus a general desire for methods of forming interconnect structures including low dielectric constant layers which are free, or substantially free, of process induced damage.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods for forming interconnect structures including low dielectric constant layers as well as semiconductor processing systems constructed and arranged for forming interconnect structures including low dielectric constant layers. As set forth in more detail below, the methods described herein enable the formation interconnect structures including low dielectric constant layers which are free of, or substantially free of, process induced damage.

In one aspect, a method of forming an interconnect structure on a substrate including a conductive layer is disclosed. The method comprises forming a plurality of trenches in the conductive layer, the trenches extending through the conductive layer to the substrate thereby forming a plurality of conductive elements, forming a passivation layer on the plurality of conductive elements, transferring the substrate from a first semiconductor processing system to a second semiconductor processing system, removing the passivation layer and filling the pluralities of trenches with a low dielectric constant layer.

In some embodiments, the steps of forming the plurality of trenches in the conductive layer and forming the passivation layer are performed in the first semiconductor processing system.

In some embodiments, the step of forming the passivation layer is performed in the first semiconductor processing system.

In some embodiments, the substrate is transferred from the first semiconductor processing system to the second semiconductor processing system after forming the passivation layer.

In some embodiments, the steps of removing the passivation layer and filling the plurality of trenches with the low dielectric constant layer are performing in the second semiconductor processing system.

In some embodiments, the steps of removing the passivation layer and filling the plurality of trenches with the low dielectric constant layer are performed in a single reaction chamber.

In some embodiments, the passivation layer is deposited hermetically on the plurality of trenches and on the plurality of conductive elements thereby sealing the plurality of trenches and the plurality of conductive elements.

In some embodiments, the passivation layer is selected from the group consisting of elemental metals, such as tungsten, molybdenum, ruthenium or tantalum, nitrides, such as silicon nitride, titanium nitride or tantalum nitride, oxides, such as silicon oxide or aluminum oxide, or carbides, such as titanium carbide or tantalum carbide.

In an aspect, a method of forming an interconnect structure on a substrate including a device region is disclosed. The method comprises depositing a conductive layer on the substrate, etching a plurality of trenches in the conductive layer, the trenches extending through the conductive layer to the substrate thereby forming a non-planar surface including a plurality of conductive elements and the plurality of trenches, depositing a passivation layer on the non-planar surface, transferring the substrate from a first semiconductor processing system to a second semiconductor processing system, etching the passivation layer to remove the passivation layer and expose the non-planar surface and depositing a low dielectric constant layer directly on the non-planar surface to fill the plurality of trenches with the low dielectric constant layer.

In some embodiments of forming an interconnect structure, the step of depositing the passivation layer is performed in the first semiconductor processing system.

In some embodiments of forming an interconnect structure, the substrate is transferred from the first semiconductor processing system to the second semiconductor processing system after forming the passivation layer.

In some embodiments of forming an interconnect structure, the steps of etching the passivation and depositing the low dielectric constant layer are performed in the second semiconductor processing system.

In some embodiments of forming an interconnect structure, the steps of etching the passivation layer and depositing the low dielectric constant layer are performed in a single reaction chamber.

In another aspect, a semiconductor processing system is disclosed. The semiconductor processing system comprises a first reaction chamber constructed and arranged for etching a passivation layer disposed over a non-planar surface of a substrate, the non-planar surface including a plurality of conductive elements and a plurality of trenches, a second reaction chamber constructed and arranged to perform a precondition process on the non-planar surface prior to depositing a low dielectric constant layer on the non-planar surface, a third reaction chamber constructed and arranged for depositing the low dielectric constant layer on the non-planar surface, a transfer module constructed and arranged for moving the substrate between the first reaction chamber, the second reaction chamber, and the third reaction chamber, while keeping the substrate in a vacuum or inert gas environment, one or more precursor/reactant sources operationally coupled with each of the first reaction chamber, the second reaction chamber, and the third reaction chamber and a controller constructed and arranged for causing the semiconductor processing system to form an interconnect structure.

In some embodiments of the semiconductor processing system, the first reaction chamber and the third reaction chamber comprise a single reaction chamber constructed and arranged for both etching the passivation layer and for depositing the low dielectric constant layer.

In some embodiments, the semiconductor processing system further comprises a metrology chamber constructed and arranged for inspecting the substrate after etching the passivation layer and/or after depositing the low dielectric constant layer.

In yet another aspect, a method of forming an interconnect structure on a substrate including a device region is disclosed. The method comprises depositing a conductive layer on the substrate, forming a patterned masking material on a top surface of the conductive layer to form a plurality of masked regions and a plurality of unmasked regions, etching the exposed regions of the conductive layer through the plurality of unmasked regions to form a plurality of trenches in the conductive layer, the trenches extending through the conductive layer to the substrate thereby forming a non-planar surface including a plurality of conductive elements and the plurality of trenches, depositing a passivation layer on the non-planar surface, transferring the substrate from a first semiconductor processing system to a second semiconductor processing system, etching the passivation layer to remove the passivation layer and depositing a low dielectric constant layer on the non-planar surface to fill the plurality of trenches with the low dielectric constant layer.

In some embodiments of forming an interconnect structure, the passivation layer and the patterned masking material can be etched by substantially the same chemistry.

In some embodiments of forming an interconnect structure, the step of etching the passivation layer further comprises also etching any residual patterned masking material.

In some embodiments of forming an interconnect structure, the steps of performing the preconditioning process to remove any residual patterned masking material and etching the passivation layer are performed in a single reaction chamber of the second semiconductor processing system.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary method for forming an interconnect structure including a low dielectric constant layer in accordance with one or more embodiments of the disclosure.

FIG. 2 illustrates a structure including a substrate and a conductive layer in accordance with one or more embodiments of the disclosure.

FIG. 3 illustrates a structure including a plurality of trenches and a plurality of conductive elements in accordance with one or more embodiments of the disclosure.

FIG. 4 illustrates a structure including a passivation layer in accordance with one or more embodiments of the disclosure.

FIG. 5 illustrates an additional structure including a plurality of trenches and a plurality of conductive elements in accordance with one or more embodiments of the disclosure.

FIG. 6 illustrates a structure including a low dielectric constant layer in accordance with one or more embodiments of the disclosure.

FIG. 7 illustrates a structure including a planarized low dielectric constant layer in accordance with one or more embodiments of the disclosure.

FIG. 8 illustrates an exemplary semiconductor processing system in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “low dielectric constant layer” or “low-k layer,” can refer to a layer of material whose dielectric constant is less than the dielectric constant of silicon dioxide or less than 4.0, less than 3.5, less than 3.0, less than 2.5, less than 2.0, less than 1.5, or between 1.5 and 4.0.

As used herein, the term “structure” can refer to a partially or completely fabricated device structure. By way of examples, a structure can be a substrate or include a substrate with one or more layers and/or features formed thereon.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Various embodiments of the present disclosure relate to methods for forming interconnect structures including low dielectric constant layers as well as associated structures and semiconductor processing systems constructed and arranged for forming such interconnect structures. As set forth in more detail below, the methods of the present disclosure form interconnect structures which include a low dielectric constant layer which is free, or substantially free, of process induced damage thereby maintaining the low dielectric constant of the low-k layer which would otherwise be shifted to higher k values in the presence of process induced damage.

Commonly employed methods of forming interconnect structures including low dielectric constant layers include “damascene” type processes. For example, a damascene type process can include, depositing a low dielectric constant layer on a substrate and subsequently etching trenches into the low dielectric constant layer to enable the deposition of a conductive layer within the trenches. The conductive layer is subsequently planarized resulting in a multitude of conductive elements (such as conductive lines and conductive vias) embedded in the low dielectric constant layer. However such prior approaches often result in process induced damage in the low dielectric constant layer as a result of the etching processes, which typically employ plasma excited fluorine and/or chlorine and/or oxygen-containing etch species which may cause damage in the low dielectric constant layer.

According to various embodiments of the present disclosure, interconnect structures are achieved at least in part by performing etching processes and subsequent passivation processes prior to forming the low dielectric constant layer of the interconnect structure thereby reducing process induced damage in the low dielectric constant layer and enabling the fabrication of interconnect structures including low dielectric constant layers with improved dielectric constants, e.g., less than 2.5, for example.

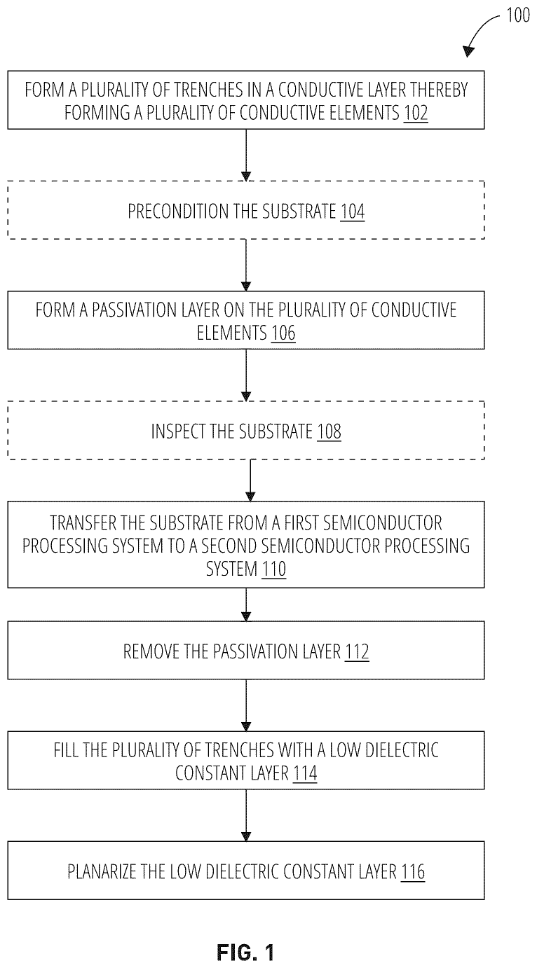

Turning now to the figures, FIG. 1 illustrates an exemplary method 100 for forming interconnect structures including damage free low dielectric constant layers according to the embodiments of the present disclosure. Briefly, method 100 includes forming a plurality of trenches in a conductive layer on a substrate, the pluralities of trenches extending through the conductive layer to the substrate thereby forming a plurality of conductive elements (step 102). Method 100 also includes, optionally preconditioning the substrate (step 104). For example, an optional preconditioning step can be performed on the substrate after forming the plurality of conductive elements. Method 100 also includes, forming a passivation layer on the plurality of conductive elements (step 106). Method 100 also includes, optionally inspecting the substrate (step 108). Method 100 also includes transferring the substrate from a first semiconductor processing system to a second semiconductor processing system (i.e., to a different reaction chamber in a different system) (step 110). Method 100 also includes removing the passivation layer (step 112) and subsequently filing the plurality of trenches with the low dielectric constant layer (step 114). Method 100 can also include planarizing the low dielectric constant layer (step 116).

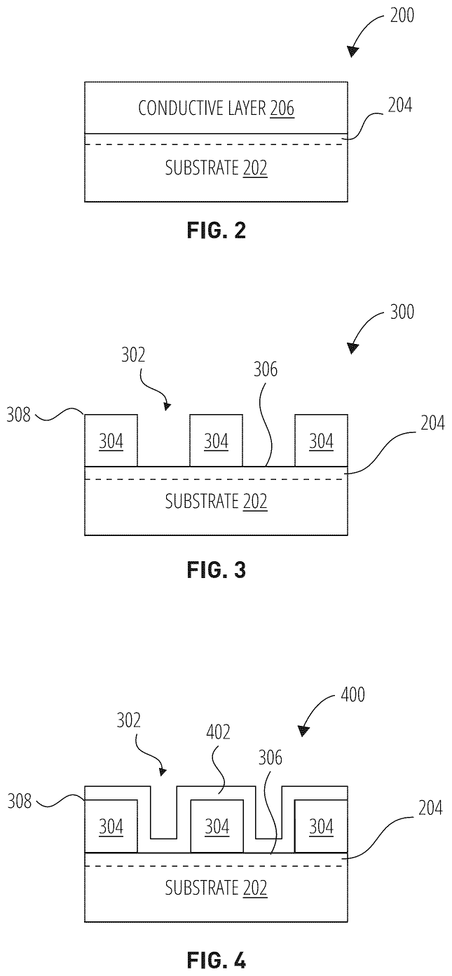

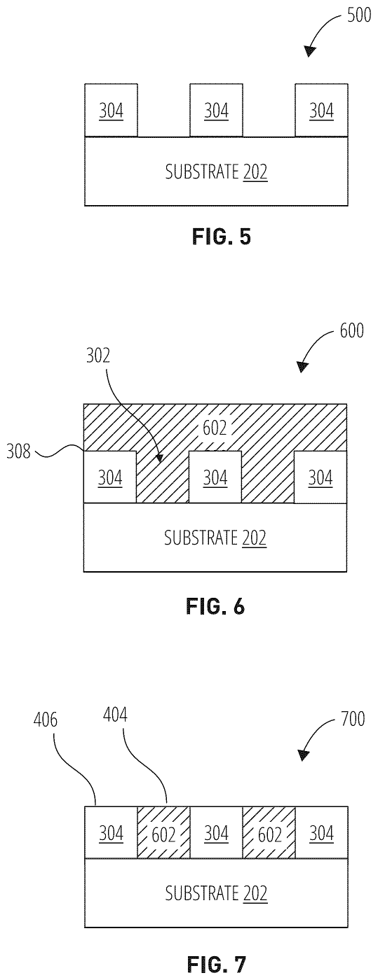

The process steps of method 100 are described in greater detail below with reference to method 100 of FIG. 1 and also with reference to FIG. 2, FIG. 3, FIG. 4, FIG. 5, FIG. 6, and FIG. 7 which together illustrate associated structures formed during the process of performing the steps of method 100, as well as additional steps that can be included as part of method 100.

In more detail, and in accordance with examples of the disclosure, method 100 (FIG. 1) includes step 102 which comprises forming a plurality of trenches in a conductive layer on a substrate. In accordance with examples of the disclosure, FIG. 2 illustrates a structure 200 including a substrate 202. In such examples, the substrate 202 can include at least one of the materials and structures as described above, such as, for example, a single crystalline semiconductor layer on at least the surface of the substrate 202.

In accordance with examples of the disclosure, the substrate 202 can include a device region 204 in which one or more devices (not shown) are formed on/in the substrate 202. In such examples, the device region 204 can include devices, such as transistors, diodes, imaging sensors, resistors, capacitors, inductors, memory cells, or a combination thereof. In some embodiments, the devices are transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels.

In accordance with examples of the disclosure, the structure 200 includes a conductive layer 206 which in subsequent process steps will become multiple conductive elements as part of an interconnect structure as described in greater detail below.

In accordance with examples of the disclosure, the conductive layer 206 comprises one or more of a metal, a metal alloy, a conductive metal nitride, a silicide, or mixtures thereof. In some embodiments, the conductive layer is selected from the group consisting of Cu, Co, Ru, Mo, Cr, W, Mn, Rh, Ir, Ni, Pd, Pt, Ag, Au, Al, FeAl, FeCo, and alloys thereof. In some embodiments, the conductive layer 206 is deposited on the substrate 202 and on the devices within the device region 204. In such embodiments, the conductive layer 206 is deposited on the substrate 202 by seating the substrate 202 in a reaction chamber and employing one or more deposition processes including, but not limited, physical vapor deposition (PVD), atomic layer deposition (ALD), chemical vapor deposition (CVD), electro-chemical plating (ECP), or a combination thereof.

After forming the conductive layer on the substrate, method 100 includes forming a plurality of trenches in the conductive layer (step 102). FIG. 3 illustrates a structure 300 including a plurality of trenches 302. In accordance with examples of the disclosure, the plurality of trenches 302 extend through the conductive layer 206 through to the substrate 202 below, thereby forming a plurality of conductive elements 304. In such examples, the plurality of trenches 302 separate the plurality of conductive elements 304 from one another as the trenches 302 extend to the underlying substrate 202. In such examples, each of the plurality of trenches 302 have a trench base 306 which is free of the conductive material of the conductive layer 206. In such examples, forming the plurality of trenches 302 in the conductive layer 206 forms a non-planar surface 308 which includes the top surfaces of the conductive elements, the sidewall surfaces of the conductive elements, and the trench base surfaces at the bottom of the trenches.

In accordance with examples of the disclosure, the plurality of conductive elements 304 formed by removing select region of the conductive layer 206 (of FIG. 2) are arranged to provide electrical pathways to the various devices disposed in the device region 204 of the substrate 202 below. In such examples, the plurality of conductive elements 304 provide vertical electrical routing from the device region 204 (and the devices therein) to the conductive elements 304, as well as horizontal electrical routing between the plurality of conductive elements 304 themselves. In such examples, the plurality of conductive elements 304 include conductive lines and conductive vias.

In accordance with examples of the disclosure, the plurality of trenches 302 are formed by patterning the surface of the conductive layer 206 with a masking material (not shown) and one or more etching processes. In such examples, the masking material (e.g., an organic layer, a metal oxide, etc.) can be formed and patterned employing any suitable process, such as lithography processes. In such examples, a plasma etch process is used, such as a plasma deep reactive ion etching (DRIE) process with an organic gas as an etchant. For example, the plasma DRIE process may use inductively coupled plasma (ICP) having a power ranging from about 100 W to about 1500 W, a bias voltage ranging from about 0 V to about 300 V, and organic etchant such as CH₃COOH, CH₃OH, CH₃CH₂OH, or combinations thereof. In another example, the ICP plasma DRIE process may have a power ranging from about 100 W to about 1500 W, a bias voltage ranging from about 0 V to about 500 V, and etchant such as CF₄, CHF₃, CH₃F, CH₂F₂, C₄F₈, C₄F₆, N₂, O₂, Ar, or combinations thereof. In yet another example, the plasma DRIE process may have a power ranging from about 100 W to about 2000 W, a bias voltage ranging from about 0 V to about 500 V, and etchant such as Cl₂, SiCl₄, BCl₃, CF₄, CHF₃, CH₂F₂, C₄F₈, C₄F₆, N₂, O₂, Ar, or combinations thereof.

After forming the plurality of conductive elements, method 100 (FIG. 1) includes forming a passivation layer on the plurality of conductive elements (step 106). In accordance with examples of the disclosure, a passivation layer is formed over the exposed surface of the plurality of conductive elements to seal the conductive elements after removing any possible post-etch residuals on the conductive elements. In such examples, the passivation layer can prevent corrosion of the conductive elements.

FIG. 4 illustrates a structure 400 including a passivation layer 402 disposed on the plurality of conductive elements 304 and on each of the trench bases 306 of the plurality of trenches 302. Once in a suitable reaction chamber constructed and arranged for depositing the passivation layer on the substrate, the step of forming the passivation layer 402 on the plurality pluralities plurality of conductive elements 304 is performed.

In accordance with examples of the disclosure, the passivation layer is formed by a deposition process. In some embodiments, the deposition process is a cyclical deposition process. In some embodiments, the cyclical deposition process is an atomic layer deposition (ALD) process. In some embodiments, the cyclical deposition process is a cyclical chemical vapor deposition process (CCVD). In some embodiments, the cyclical deposition process is a hybrid ALD/CCVD process. In some embodiments, the passivation layer 402 is deposited conformally directly on the non-planar surface 308 with a conformality of at least 80%, or 85%, or 90%, or 95% or higher conformality. As used herein, the term “conformality” can refer to the ratio of the average thickness of the passivation layer 402 on the top surfaces of the plurality of conductive elements 304 compared with the average thickness of the passivation layer 402 deposited on the sidewall surfaces of the plurality of conductive elements 304. In some embodiments, the passivation is deposited by a non-conformal deposition process.

In accordance with examples of the disclosure, the passivation layer is formed at a deposition temperature (e.g., a substrate temperature) of less than 300° C., less than 250° C., less than 200° C., less than 150° C., or less than 100° C. In such examples, the passivation is deposited at a deposition temperature between 100° C. and 300° C. In such examples, the deposition temperature of the passivation layer can be at least partially dependent on the material of the conductive layer. In some embodiments, the deposition temperature is below the temperature at which deformation of the conductive elements can occur.

In accordance with examples of the disclosure, the passivation layer 402 is a closed layer. In such examples, the passivation layer 402 seals the underlying plurality of conductive elements 304 and the trench base 306 regions between the conductive elements. In such examples, the passivation layer 402 is free of voids extending from the surface of the passivation layer to the underlying plurality of conductive elements 304 to enable the sealing of the plurality of conductive elements 304. In accordance with examples of the disclosure, the passivation layer 402 is an impermeable layer. In such examples, the passivation layer is deposited hermetically on the plurality of trenches and on the plurality of conductive elements thereby sealing the plurality of trenches and the plurality of conductive elements.

In accordance with examples of the disclosure, the passivation layer 402 is a continuous layer. In some embodiments, the passivation layer 402 is deposited with an average layer thickness of less than 5 nm, less than 4 nm, less than 3 nm, less than 2 nm, or less than 1 nm. In some embodiments, the passivation layer 402 is deposited to with an average layer thickness between 1 nm and 5 nm. In some embodiments, the passivation layer 402 is deposited with an average layer thickness of greater than 5 nm, greater 8 nm, greater than 10 nm, greater than 13 nm, greater than 15 nm, or between 5 nm and 15 nm. In some embodiments, the passivation layer 402 is deposited as a closed, continuous film, with an average layer thickness between 1 nm and 5 nm, and with a conformality greater than 90%.

In accordance with examples of the disclosure, the passivation layer 402 comprises at least one of a metal, a semiconductor, a dielectric, or a polymer. In such examples, the passivation layer 402 is selected from the group consisting of elemental metals, such as tungsten, molybdenum, ruthenium or tantalum, nitrides, such as silicon nitride, titanium nitride or tantalum nitride, oxides, such as silicon oxide or aluminum oxide, or carbides, such as silicon carbide. In some embodiments, the passivation layer 402 comprises silicon. In some embodiments, the passivation layer 402 comprises nitrogen. In some embodiments, the passivation layer 402 comprises carbon. In some embodiments, the passivation layer 402 comprises oxygen. In some embodiments, the passivation layer 402 is selected from silicon oxide, silicon nitride, aluminum oxide, tungsten, molybdenum, ruthenium, titanium nitride, tantalum. In some embodiments, the passivation layer 402 comprises at least one of a metal oxide, or a metal nitride.

In some embodiments, the passivation layer comprises organic material. In some embodiments, the passivation layer comprises, consists essentially, or consists of an organic polymer. In some embodiments, the passivation layer comprises, consists essentially, or consists of polyimide. In some embodiments, the passivation layer comprises, consists essentially, or consists of polyamic acid. In some embodiments, the passivation layer is deposited by molecular layer deposition. In some embodiments, the passivation layer is deposited at temperatures below 190° C., and subsequently heat-treated (annealed) at a temperature of about 190° C. or higher (such as from about 200° C. to about 500° C.) to increase the proportion of the organic polymer from polyamic acid to polyimide. Other examples of deposited organic polymers include dimers, trimers, polyurethanes, polythioureas, polyesters, polyimines, other polymeric forms or mixtures of the above materials. In some embodiments, the deposited organic polymer is exposed to reactive species generated from plasma. This may improve the passivation properties of the organic polymer in embodiments in which it is used as a passivation material. For example, reactive species generated from hydrogen- and argon-comprising plasma can be used. The organic polymer may be exposed to plasma from about 1 seconds to about 1 minute, such as from about 1 second to about 30 seconds, or from about 5 seconds to about 30 seconds, or for about 1 second to about 15 seconds, or from about 3 seconds to about 20 seconds.

In accordance with examples of the disclosure, the passivation layer 402 comprises a material which is selectivity removeable. In such examples, the passivation layer 402 is a material with an etch selectivity (compared with the material of the plurality of conductive elements 304) of greater than 100%, greater than 200%, greater than 300%, greater than 500%, greater than 1000%, or greater.

Without limiting the current disclosure to any specific theory, an advantageous passivation layer may be a hermetic layer (i.e. preventing or at least reducing oxygen access to the surface of the substrate). Further, an advantageous passivation layer may be formed, such as deposited, on the substrate in low temperature. A low temperature for forming a passivation layer may be, for example, below 250° C., or below 200° C. A further advantageous feature of a passivation layer maybe the possibility to remove it easily before further processing of the substrate.

In accordance with addition examples of the disclosure, the plurality of conductive elements can optionally be subjected to one or more preconditioning processes (step 104) prior to forming the passivation layer on the plurality of conductive element (step 106). In such embodiments the preconditioning process (step 104) can remove any undesirable residuals remaining on the surface of the plurality of conductive elements to enhance adhesion of the passivation layer to the plurality of conductive elements, for example. As a non-limiting example, a preconditioning process can be performed prior to forming the passivation layer to remove any remaining portions of the masking material employed during the formation of the plurality of trenches. In such examples, the one or more preconditioning processes (step 104) can include thermal and/or chemical processes. In some embodiments, preconditioning comprises removing etch residues from the substrate surface. In some embodiments, preconditioning comprises reducing or removing oxides on the surface. For example, reconditioning may comprise treating the substrate with plasma, such as plasma comprising H₂ and/or NH₃. In other examples, the optional preconditioning step (step 104) can be repeated, or employed, prior to subsequent steps of method 100 as described in detail below.

In accordance with additional examples of the disclosure, the substrate can optionally be inspected (step 108). In some embodiments, the substrate can be inspected after forming the forming the passivation layer on the conductive elements, i.e., after performing step 106 of method 100 (FIG. 1). In such examples, the substrate can be inspected to determine if the dimensions of the plurality of conductive elements 304 and the plurality of trenches 302, with the passivation layer 402 disposed thereon, are within an expected range of values. The inspection process can comprise observing the substrate surface with a metrology tool to determine that the critical dimensions of the plurality of conductive elements 304 and the plurality of trenches 302 (with the passivation layer disposed thereon) are within an expected range.

In accordance with examples of the disclosure, the optional inspection process (step 108) can be performed by removing the substrate from the semiconductor processing systems employed to form the passivation layer and inspecting the critical dimensions of the substrate ex-situ, e.g., using a metrology tool separate from the semiconductor processing system.

In accordance with other examples of the disclosure, the optional inspection process (step 108) can be performed within the same semiconductor processing systems employed to form the passivation layer. In such embodiments, inspecting the critical dimensions of the substrate is performed in-situ, e.g., using a metrology tool within the same semiconductor processing system employed to form the passivation layer. In such examples, the step of forming the passivation layer (step 106) is performed in a first reaction chamber and the step of inspecting the substrate (step 108) is performed in a second chamber (i.e., a metrology chamber) constructed and arranged to inspect the critical dimensions of the substrate. In such examples, the substrate can be transferred employing a transfer module which is constructed and arranged for moving the substrate between the first reaction chamber used for forming (e.g., depositing) the passivation layer to the second chamber (i.e., the metrology chamber) while keeping the substrate in a vacuum or inert gas environment.

Method 100 (FIG. 1) also includes the step of removing the passivation layer (step 112). In accordance with examples of the disclosure, the passivation layer is removed prior to forming the low dielectric constant layer, as discussed in greater detail below. In such examples, the passivation layer 402 protects the non-planar surface 308 of the substrate 202 (FIG. 4) prior to the formation of the low dielectric constant layer and is removed prior to formation of the low dielectric constant layer to enable formation of the low dielectric constant layer directly on the non-planar surface 308. In accordance with examples of the disclosure, the passivation layer hermetically seams the underlying plurality of conductive elements. In such examples, the passivation layer prevents corrosion of the plurality of conductive elements. In such examples, the passivation layer prevents corrosion of the plurality of conductive elements as the substrate (including the conductive elements) is queue for subsequent process steps, and/or the substrate is transferred between different semiconductor processing systems, and/or the substrate is transferred between the different reaction chambers of a semiconductor processing system, and/or the substrate is transferred to a metrology chamber to perform inspection processes.

FIG. 5 illustrates a structure 500 after the removal of the passivation layer 402. Once in a suitable reaction chamber constructed and arranged for removing the passivation layer on the substrate, the step of removing the passivation layer 402 from the plurality pluralities plurality of conductive elements 304 is performed (step 112). In such examples, the passivation layer 402 is completely removed during the removal step 112 to expose the non-planar surface 308.

In accordance with examples of the disclosure, the passivation layer 402 is removed by one or more etching processes. In some embodiments, the passivation layer is removed by a chemical vapor etch process. In such embodiments, the substrate is heated to a temperature of less than 300° C., less than 250° C., less than 200° C., less than 150° C., less than 100° C., or between 100° C. and 300° C. and a vapor etchant is introduced into the reaction chamber to remove the passivation layer. In some embodiments, the vapor etchant is a selective etchant. In such embodiments, the selective etchant selectively removes the passivation without etching, or significantly etching the underlying materials (e.g., the conductive elements 304 and the substrate 202). As a non-limiting example, the passivation layer can include a silicon dioxide layer and the silicon dioxide passivation layer is removed by a chemical vapor etch process by heating the substrate to a temperature of less than 300° C. and introducing a hydrofluoric acid vapor into the reaction chamber. In other examples, the passivation layer 402 is removed by a plasma etching process.

In accordance with examples of the disclosure, the steps of forming the passivation layer (step 106) and removing the passivation layer (step 112) are performed in different semiconductor processing systems. In such examples, the step of forming the passivation layer (step 106) is performed in a first semiconductor processing system and the step of removing the passivation layer (step 112) is performed in a second semiconductor processing system (different from the first reaction chamber).

In accordance with examples of the disclosure, a method of forming an interconnect structure on a substrate including a device region is disclosed. The method comprises depositing a conductive layer on the substrate, forming a patterned masking material on a top surface of the conductive layer to form a plurality of masked regions and a plurality of unmasked regions, and etching the exposed regions of the conductive layer through the plurality of unmasked regions to form a plurality of trenches in the conductive layer, wherein the trenches extend through the conductive layer to the substrate thereby forming a non-planar surface including a plurality of conductive elements and the plurality of trenches. The method further comprises depositing a passivation layer on the non-planar surface, transferring the substrate from a first semiconductor processing system to a second semiconductor processing system, etching the passivation layer to remove the passivation layer, and depositing a low dielectric constant layer on the non-planar surface to fill the plurality of trenches with the low dielectric constant layer.

In some embodiments, the passivation layer and the patterned masking material can be etched by substantially the same chemistry. In some embodiments, the passivation layer and the patterned masking material can be etched by the same chemistry. In some embodiments, the passivation layer and the patterned masking material have substantially the same, or the same, etch contrast to the materials of the non-planar surface 308.

In some embodiments, the step of etching the passivation layer further comprises also etching any residual patterned masking material. In other words, etching the passivation layer may be performed at least partially simultaneously with etching patterned masking material. In some embodiments, the passivation layer is etched in the same reaction chamber as residual patterned masking material.

In some embodiments, the method further comprises performing a preconditioning process to remove any residual patterned masking material. In some embodiments, the steps of performing the preconditioning process to remove any residual patterned masking material and etching the passivation layer are performed in a single reaction chamber of the second semiconductor processing system. In some embodiments, preconditioning comprises contacting the surface with a reducing agent, or a gas targeted for modifying surface terminations available for further processing.

Method 100 (FIG. 1) also includes the step of filling the plurality of trenches with a low dielectric constant layer (step 114). In some embodiments step 114 comprises depositing a low dielectric constant layer directly on the non-planar surface of the substrate to fill the plurality of trenches with the low dielectric constant layer.

FIG. 6 illustrates a structure 600 after forming the low dielectric constant layer 602 on the non-planar surface 308 of the substrate 202, thereby filling the plurality of trenches 302. Once in a suitable reaction chamber constructed and arranged for forming the low dielectric constant layer 602, the step of forming the low dielectric constant layer 602 on the non-planar surface 308 of the substrate 202 thereby filling the plurality of trenches 302 is performed (step 112). In such examples, the low dielectric constant layer 602 fills the pluralities plurality of trenches 302 and covers the top surface of the plurality of conductive elements 304.

In accordance with examples of the disclosure, the low dielectric constant layer 602 is layer having a dielectric constant less than that silicon dioxide (e.g., less than 4.0). In such examples, the low dielectric constant layer 602 can include at least one of a doped silicon dioxide (e.g., Fluorine-doped SiO₂), a silicon oxycarbide (SiOC), an organosilicate glass, a porous silicon dioxide, a porous organosilicate glass, a porous silicon oxycarbide, a polymeric dielectric, or combinations thereof. In additional examples, the low dielectric constant layer 602 can include air gaps. In accordance with examples of the disclosure, the low dielectric constant layer 602 can be formed by one or more deposition methods including, but not limited, spin-on methods, chemical vapor deposition, flowable chemical vapor deposition, plasma enhanced chemical vapor deposition, atomic layer deposition, plasma-enhanced atomic layer deposition, and physical vapor deposition.

In accordance with examples of the disclosure, the low dielectric constant layer 602 formed within the plurality of trenches 302 is free, or substantially free, of process induced damage. In such examples, the low dielectric constant layer 602 maintains its as-deposited dielectric constant. In such examples, the low dielectric constant layer 602 has a dielectric constant of less than 3.9, less than 3.5, less than 3.0, less than 2.5, less than 2.0, less than 1.5, or between 1.5 and 3.9.

In accordance with additional examples of the disclosure, prior to forming the low dielectric constant layer 602 the optional step of preconditioning the substrate (step 104) can be performed. In such examples, the plurality of conductive elements can optionally be subjected to one or more preconditioning processes (step 104) prior to filling the plurality of trenches with a low dielectric constant layer (step 114). In such embodiments the optional preconditioning process (step 104) can remove any undesirable residuals remaining on the surface of the plurality of trenches to enhance adhesion of the low dielectric constant layer in the plurality of trenches, for example. As a non-limiting example, a preconditioning process can be performed prior to forming the low dielectric constant layer to remove any remaining portions of the masking material employed during the formation of the plurality of trenches. In such an example, the optional preconditioning of substrate (step 104) can be performed if the preconditioning of the substrate was not performed prior to forming the passivation layer.

In accordance with examples of the disclosure, the steps of removing the passivation layer (step 112), preconditioning the substrate (step 104) prior to low dielectric constant layer formation, and forming the low dielectric constant layer (step 114) can be performed in a second semiconductor processing system.

In accordance with examples of the disclosure, the various steps of exemplary method 100 can be performed in one or more reaction chambers either as part of a single semiconductor processing system or as one or more reactions on multiple semiconductor processing systems. The following non-limiting examples describe exemplary process flows for performing method 100 (FIG. 1) and the semiconductor processing system utilized in performing the exemplary process flows.

### Exemplary Process Flow #1

In accordance with examples of the disclosure, method 100 comprises forming the plurality of trenches in the conductive layer (step 102). The steps of preconditioning the substrate to remove any residuals (step 104) and forming the passivation layer (step 106) are performed in a first semiconductor processing system. The method 100 can then optionally include inspecting the substrate (step 108) or alternatively holding the substrate for a time period prior to the subsequent process step. The method 100 can continue with the steps of removing the passivation layer (step 112) and forming the low dielectric constant layer (step 114) in a second semiconductor processing system.

### Exemplary Process Flow #2

In accordance with additional examples of the disclosure, method 100 comprises forming the plurality of trenches in the conductive layer (step 102). The step of forming the passivation layer (step 106) is performed in a first semiconductor processing system. The method 100 can then optionally include inspecting the substrate (step 108) or alternatively holding the substrate for a time period prior to the subsequent process step. The method can continue with the steps of preconditioning the substrate (step 104), removing the passivation layer (step 112), and forming the low dielectric constant layer (step 114) in a second semiconductor processing system.

### Exemplary Process Flow #3

In accordance with further examples of the disclosure, method 100 comprises forming the plurality of trenches in the conductive layer (step 102), preconditioning the substrate (step 104), and forming the passivation layer (step 106) in a first semiconductor processing system. The method 100 can then optionally include inspecting the substrate (step 108) or alternatively holding the substrate for a time period prior to the subsequent process step. The method 100 can continue with the steps of removing the passivation layer (step 112) and forming the low dielectric constant layer (step 114) in a second semiconductor processing system.

### Exemplary Process Flow #4

In accordance with yet further examples of the disclosure, method 100 comprises forming the plurality of trenches in the conductive layer (step 102) and forming the passivation layer (step 106) in a first semiconductor processing system. The method 100 can then optionally include inspecting the substrate (step 108) or alternatively holding the substrate for a time period prior to the subsequent process step. The method 100 can continue with the steps of removing the passivation layer (step 112), preconditioning the substrate (step 104) and forming the low dielectric constant layer (step 114) in a second semiconductor processing system.

In accordance with examples of the disclosure, the exemplary process flows described above can include one or more substrate transfers between different reaction chamber (step 110) when two or more of the process steps are performed in the same semiconductor processing system. In some embodiments, when two or more of the process steps of method 100 are performed in the same semiconductor processing system, the two or more process steps of method 100 may be performed within the same reaction chamber of the semiconductor processing system. As a non-limiting example, the steps of removing the passivation layer (step 112) and forming the low dielectric constant layer (step 114) can be performed in the same reaction chamber of a semiconductor processing system. In such examples, method 100 includes removing the passivation layer (step 112), and subsequently forming the low dielectric constant layer (step 114) wherein step 112 and step 114 are performed in the same reaction chamber without performing intervening processes, i.e., the low dielectric constant layer is formed directly after removing the passivation layer.

Method 100 (FIG. 1) can also include the step of planarizing the low dielectric constant layer (step 116).

FIG. 7 illustrates a structure 700 after planarizing the low dielectric constant layer 602. In accordance with examples of the disclosure, a planarization process can be performed to remove a portion of the low dielectric constant layer 602 formed over the top surface of the plurality of conductive elements 304. The planarization process may be any suitable process, such as a chemical-mechanical polishing (CMP) process, an etch-back process, or combination of the two. As a result of the planarization process, a top surface 404 of the low dielectric constant layer may be substantially coplanar with a top surface 406 of the plurality of conductive elements 304.

Various embodiments of the current disclosure also relate semiconductor processing systems constructed and arranged for performed the methods described above for forming interconnect structures.

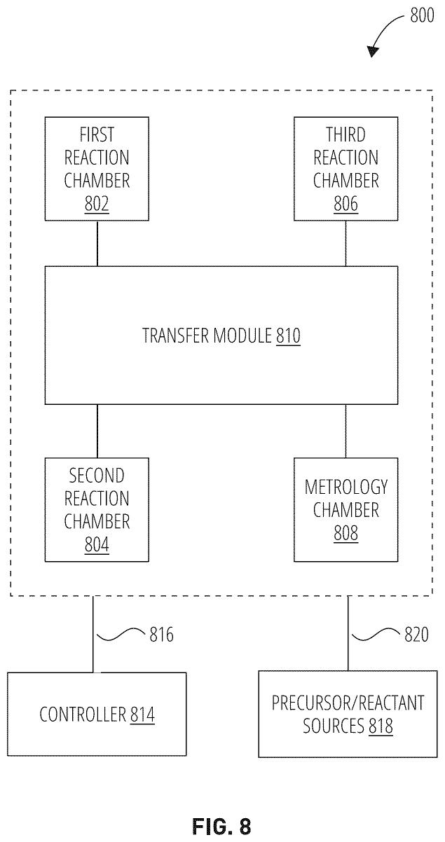

FIG. 8 illustrates an exemplary semiconductor processing system 800 including a first reaction chamber 802, a second reaction chamber 804, a third reaction chamber 806, and an optional metrology chamber 808. In accordance with examples of the disclosure, the semiconductor processing system 800 includes a transfer module 810 to transfer substrates between the first, second, third reaction chambers, and the optional metrology chamber under vacuum or an inert atmosphere. Semiconductor processing system 800 includes a controller 814 operably connected to the first reaction chamber 802, the second reaction chamber 804, the third reaction chamber 806, the metrology chamber 808, and the transfer module 810 via link 816 (e.g., a physical or wireless link). The controller 814 is constructed and arranged for causing the semiconductor processing system 800 to perform the steps of method 100, as described above. In accordance with examples of the disclosure, the first reaction chamber 802, the second reaction chamber 804, the third reaction chamber 806, and the metrology chamber 808 can be operationally coupled with one or more precursor/reactant sources 818 via gas channels 820.

In accordance with examples of the disclosure, the first reaction chamber 802 is constructed and arranged for etching a passivation layer disposed over a non-planar surface of a substrate, the non-planar surface including a plurality of conductive elements and a plurality of trenches (as described with reference to step 112 of method 100).

In accordance with examples of the disclosure, the second reaction chamber is constructed and arranged to perform precondition processes on the non-planar surface prior to depositing the low dielectric constant layer on the non-planar surface (as described with reference to step 104 of method 100).

In accordance with examples of the disclosure, the third reaction chamber is constructed and arranged for depositing a low dielectric constant layer on the non-planar surface (as described with reference to step 114 of method 100).

In accordance with examples of the disclosure, the first reaction chamber 802 and the third reaction chamber 806 can comprise a single reaction chamber constructed and arranged for both etching the passivation layer and for depositing the low dielectric constant layer. In such examples, the substrate does not require a transfer process between reaction chambers and/or between different semiconductor processing systems when performing both the etching the passivation layer and the deposition of the low dielectric constant layer.

In accordance with additional examples of the disclosure, the semiconductor processing system 800 can optionally include a metrology chamber 808 constructed and arranged for inspecting the substrate. In such examples, the substrate can be inspected after etching the passivation layer in the first reaction chamber, and/or after performing the precondition process on the non-planar surface prior to depositing the low dielectric constant layer, and/or after depositing the low dielectric constant layer.

In accordance with examples of the disclosure, the transfer module 810 is constructed and arranged for transferring a substrate between the first reaction chamber 802, the second reaction chamber 804, and the third reaction chamber 806, and the option metrology chamber 808 under vacuum or an inert atmosphere (as described with reference to step 110 of method 100).

In some embodiments of the disclosure, an additional semiconductor processing system (not shown) can be employed for performing the steps of method 100 prior to etching the passivation layer (step 112), i.e., prior to transferring the substrate to the semiconductor processing system 800 of FIG. 8.

In accordance with additional examples of the disclosure, an initial semiconductor processing system (not shown) is employed for etching the plurality of trenches in the conductive layer. In such examples, the initial semiconductor processing system can optional include a metrology chamber for inspecting the substrate after forming the trenches to confirm the critical dimensions of the trenches in the conductive layer. In some embodiments, the substrate is transferred from the initial semiconductor processing system to an additional semiconductor processing system including a first reaction chamber constructed and arranged for performing preconditioning processes on the plurality of conductive elements and a second reaction chamber constructed and arranged for depositing the passivation layer. In some embodiments, the substrate is transferred from the initial semiconductor processing system to an additional semiconductor processing system including a first reaction chamber constructed and arranged for depositing the passivation layer.

In accordance with additional examples of the disclosure, an additional processing system can include a first reaction constructed arranged for etching a plurality of trenches in a conductive layer, a second reaction chamber constructed and arranged to perform a precondition process on the plurality of trenches prior to passivation layer formation, and a third reaction chamber constructed and arranged for depositing the passivation layer.

In accordance with examples of the disclosure, an additional semiconductor processing system can include a first reaction constructed arranged for etching a plurality of trenches in a conductive layer and second reaction chamber constructed and arranged for depositing the passivation layer.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of forming an interconnect structure on a substrate including a conductive layer, the method comprising:
forming a plurality of trenches in the conductive layer, the trenches extending through the conductive layer to the substrate thereby forming a plurality of conductive elements;
forming a passivation layer on the plurality of conductive elements;
transferring the substrate from a first semiconductor processing system to a second semiconductor processing system;
removing the passivation layer; and
filling the pluralities of trenches with a low dielectric constant layer.

2. The method of claim 1, wherein the steps of forming the plurality of trenches in the conductive layer and forming the passivation layer are performed in the first semiconductor processing system.

3. The method of claim 1, wherein the step of forming the passivation layer is performed in the first semiconductor processing system.

4. The method of claim 3, further comprising performing a preconditioning process on the plurality of conductive elements prior to forming the passivation layer.

5. The method of claim 3, further comprising inspecting the substrate after forming the passivation layer.

6. The method of claim 3, wherein the substrate is transferred from the first semiconductor processing system to the second semiconductor processing system after forming the passivation layer.

7. The method of claim 6, wherein the steps of removing the passivation layer and filling the plurality of trenches with the low dielectric constant layer are performing in the second semiconductor processing system.

8. The method of claim 7, wherein the steps of removing the passivation layer and filling the plurality of trenches with the low dielectric constant layer are performed in a single reaction chamber.

9. The method of claim 8, further comprises performing a preconditioning process on the plurality of conductive elements after removing the passivation layer and prior to filling the plurality of trenches with the low dielectric constant layer.

10. The method of claim 1, wherein the passivation layer is deposited hermetically on the plurality of trenches and on the plurality of conductive elements thereby sealing the plurality of trenches and the plurality of conductive elements.

11. The method of claim 1, wherein the passivation layer is selected from the group consisting of elemental metals, such as tungsten, molybdenum, ruthenium or tantalum, nitrides, such as silicon nitride, titanium nitride or tantalum nitride, oxides, such as silicon oxide or aluminum oxide, or carbides, such as silicon carbide.

12. A method of forming an interconnect structure on a substrate including a device region, the method comprising:
depositing a conductive layer on the substrate;
etching a plurality of trenches in the conductive layer, the trenches extending through the conductive layer to the substrate thereby forming a non-planar surface including a plurality of conductive elements and the plurality of trenches;
depositing a passivation layer on the non-planar surface;
transferring the substrate from a first semiconductor processing system to a second semiconductor processing system;
etching the passivation layer to remove the passivation layer and expose the non-planar surface; and
depositing a low dielectric constant layer directly on the non-planar surface to fill the plurality of trenches with the low dielectric constant layer.

13. The method of claim 12, wherein the step of depositing the passivation layer is performed in the first semiconductor processing system.

14. The method of claim 13, further comprising performing a preconditioning process on the plurality of conductive elements prior to depositing the passivation layer.

15. The method of claim 13, wherein the substrate is transferred from the first semiconductor processing system to the second semiconductor processing system after forming the passivation layer.

16. The method of claim 15, wherein the steps of etching the passivation and depositing the low dielectric constant layer are performed in the second semiconductor processing system.

17. The method of claim 16, wherein the steps of etching the passivation layer and depositing the low dielectric constant layer are performed in a single reaction chamber.

18. A semiconductor processing system comprising:
a first reaction chamber constructed and arranged for etching a passivation layer disposed over a non-planar surface of a substrate, the non-planar surface including a plurality of conductive elements and a plurality of trenches;
a second reaction chamber constructed and arranged to perform a precondition process on the non-planar surface prior to depositing a low dielectric constant layer on the non-planar surface;
a third reaction chamber constructed and arranged for depositing the low dielectric constant layer on the non-planar surface;
a transfer module constructed and arranged for moving the substrate between the first reaction chamber, the second reaction chamber, and the third reaction chamber, while keeping the substrate in a vacuum or inert gas environment;
one or more precursor/reactant sources operationally coupled with each of the first reaction chamber, the second reaction chamber, and the third reaction chamber; and
a controller constructed and arranged for causing the semiconductor processing system to form an interconnect structure.

19. The semiconductor processing system of claim 18, wherein the first reaction chamber and the third reaction chamber comprise a single reaction chamber constructed and arranged for both etching the passivation layer and for depositing the low dielectric constant layer.

20. The semiconductor processing system of claim 18, further comprising a metrology chamber constructed and arranged for inspecting the substrate after etching the passivation layer and/or after depositing the low dielectric constant layer.
